(19) United States
(12) Patent Application Publication
(10) Pub. No.: US 2024/0213934 A1
(43) Pub. Date: Jun. 27, 2024

(54) POWER AMPLIFIER

(71) Applicant: SAMSUNG ELECTRO-MECHANICS CO., LTD., Suwon-si (KR)

(72) Inventors: Youngwong JANG, Suwon-si (KR); Jeonghoon KIM, Suwon-si (KR); Shinichi IIZUKA, Suwon-si (KR); Hyejin LEE, Suwon-si (KR); Jongok HA, Suwon-si (KR)

(73) Assignee: SAMSUNG ELECTRO-MECHANICS CO., LTD., Suwon-si (KR)

(21) Appl. No.: 18/308,104

(22) Filed: Apr. 27, 2023

(30) Foreign Application Priority Data
Dec. 23, 2022 (KR) 10-2022-0182693

(51) Int. Cl. H03F 3/21; H03F 1/02; H03F 1/52

(52) U.S. Cl. CPC H03F 3/21; H03F 1/0216; H03F 1/52

(57) ABSTRACT

A power amplifier includes: a power transistor to receive a power voltage; a first transistor including a first terminal to provide a bias current to the power transistor; and an overpower protection circuit to generate a first current corresponding to the power voltage and to provide the first current to a second terminal of the first transistor. The overpower protection circuit includes: a limiting current source to provide a limiting current to the second terminal of the first transistor; and a sink current generating circuit including a second transistor that includes a control terminal to which a voltage corresponding to the power voltage is applied and a first terminal connected to the second terminal of the first transistor, and to sink a second current from the limiting current.

### CROSS-REFERENCE TO RELATED APPLICATION

This application claims priority to and the benefit under 35 USC 119(a) of Korean Patent Application No. 10-2022-0182693 filed in the Korean Intellectual Property Office on Dec. 23, 2022, the entire contents of which are incorporated herein by reference for all purposes.

### BACKGROUND

### Field

The following description relates to a power amplifier.

### Description of the Background

Wireless communication systems apply various digital modulation and demodulation schemes according to the evolution of communication standards. The existing code division multiple access (CDMA) communication system adopts the quadrature phase shift keying (QPSK) method, and the wireless LAN following the IEEE communication standard adopts the orthogonal frequency division multiplexing (OFDM) method. In addition, long term evolution (LTE) and LTE-Advanced, which are recent 3GPP standards, adopt QPSK, quadrature amplitude modulation (QAM), and OFDM schemes.

A transmitter used in a wireless communication system includes a power amplifier that amplifies a radio frequency (RF) signal to increase a transmission distance.

When a power voltage supplied to the power amplifier exceeds a threshold level, a situation in which the power amplifier transmits power exceeding its physical limit may occur. A method of protecting the power amplifier in this situation is called overvoltage protection (OVP). Here, a situation in which the power voltage exceeds the threshold level may occur when a battery voltage is unstable.

On the other hand, when a load impedance of the power amplifier is changed, a large amount of current flows, which may cause a situation in which the power amplifier transmits power exceeding its physical limit. Accordingly, it may be necessary to design a power amplifier that stably operates even in a situation in which an output current of a design limit or more is applied thereto. A technique of limiting an output current of a power amplifier is called overcurrent protection (OCP).

However, conventionally, OVP and OCP independently operate, and a power aspect is not considered. Because of this, the power amplifier may not be properly protected in abnormal situations.

The above information disclosed in this Background section is only for enhancement of understanding of the background of the disclosure, and therefore it may contain information that does not form the prior art that is already known in this country to a person of ordinary skill in the art.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a power amplifier includes: a power transistor configured to receive a power voltage; a first transistor including a first terminal configured to provide a bias current to the power transistor; and an overpower protection circuit configured to generate a first current corresponding to the power voltage and to provide the first current to a second terminal of the first transistor. The overpower protection circuit includes: a limiting current source configured to provide a limiting current to the second terminal of the first transistor; and a sink current generating circuit including a second transistor that includes a control terminal to which a voltage corresponding to the power voltage is applied and a first terminal connected to the second terminal of the first transistor, and configured to sink a second current from the limiting current.

When the power voltage increases, the second current may increase, and the first current may decrease.

When the power voltage is higher than a first voltage, the first current may decrease as the power voltage increases.

The first current may have a value obtained by subtracting the second current from the limiting current.

The sink current generating circuit may include a first resistor including a first end connected to the power voltage and a second resistor connected between a second end of the first resistor and a ground, and the second end of the first resistor may be connected to the control terminal of the second transistor.

The sink current generating circuit may further include a third resistor connected to a second terminal of the second transistor and the ground.

The second current may flow from the second terminal of the first transistor to the first terminal of the second transistor.

The first terminal of the first transistor may be an emitter, and the second terminal of the first transistor may be a collector.

In another general aspect, a power amplifier includes: a power transistor configured to receive a power voltage; a first transistor including a first terminal configured to provide a bias current to the power transistor; and an overpower protection circuit configured to generate a first current corresponding to the power voltage and to provide the first current to a second terminal of the first transistor. The overpower protection circuit is configured to generate the first current having a first value when the power voltage is higher than a first reference voltage, and the overpower protection circuit is configured to generate the first current having a second value when the power voltage is higher than a second reference voltage, and the second reference voltage is higher than the first reference voltage, and the second value is smaller than the first value.

The overpower protection circuit may generate the first current having a third value when the power voltage is lower than the first reference voltage, and the third value may be larger than the first value.

The overpower protection circuit may include a first comparator that compares the power voltage and the first reference voltage, and a second comparator that compares the power voltage and the second reference voltage.

The overpower protection circuit may further include a logic circuit that receives an output of the first comparator and an output of the second comparator and generates a logic signal, and a current source that generates the first current in response to the logic signal.

The first terminal of the first transistor may be an emitter, and the second terminal of the first transistor may be a collector.

In another general aspect, a power amplifier includes: a power transistor configured to receive a power voltage; a transistor configured to provide a bias current to the power transistor; and an overpower protection circuit configured to: generate a first current having a first value based on a comparison between the power voltage and a first reference voltage; generate a second current having a second value based on a comparison between the power voltage and a second reference voltage; and provide the first current or the second current to the transistor.

The second reference voltage may be higher than the first reference voltage, and the second value may be smaller than the first value.

The overpower protection circuit may include: a limiting current source configured to provide a limiting current to the transistor; and a sink current generating circuit including a second transistor that includes a control terminal to which a voltage corresponding to the power voltage is applied and a first terminal connected to the transistor, and configured to sink a second current from the limiting current.

Other features and aspects will be apparent from the following detailed description, the drawings, and the claims.

### BRIEF DESCRIPTION OF THE DRAWINGS

FIG. 1 illustrates a power amplifier according to an example.

FIG. 2 illustrates an example of a bias circuit according to an example.

FIG. 3 illustrates an overpower protection circuit according to an example.

FIG. 4 illustrates a graph of a relationship between a power voltage VCC and an adjustment limiting current I_{LIM_ADJ} in the overpower protection circuit of FIG. 3.

FIG. 5 illustrates an overpower protection circuit according to another example.

FIG. 6 illustrates a graph of a relationship between a power voltage VCC and an adjustment limiting current I_{LIM_ADJ} in the overpower protection circuit of FIG. 5.

Throughout the drawings and the detailed description, the same reference numerals refer to the same elements. The drawings may not be to scale, and the relative size, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that would be well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will fully convey the scope of the disclosure to one of ordinary skill in the art.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The drawings may not be to scale, and the relative sizes, proportions, and depiction of elements in the drawings may be exaggerated for clarity, illustration, and convenience.

Herein, an RF signal includes Wi-Fi (IEEE 802.11 family, etc.), WiMAX (IEEE 802.16 family, etc.), IEEE 802.20, LTE (long term evolution), Ev-DO, HSPA+, HSDPA+, HSUPA+, EDGE, GSM, GPS, GPRS, CDMA, TDMA, DECT, Bluetooth, 3G, 4G, 5G, and any other wireless and wired protocols designated thereafter, but is not limited thereto.

In addition, unless explicitly described to a first contrary, the word “comprise” and variations such as “comprises” or “comprising” will be understood to imply the inclusion of stated elements but not the exclusion of any other elements.

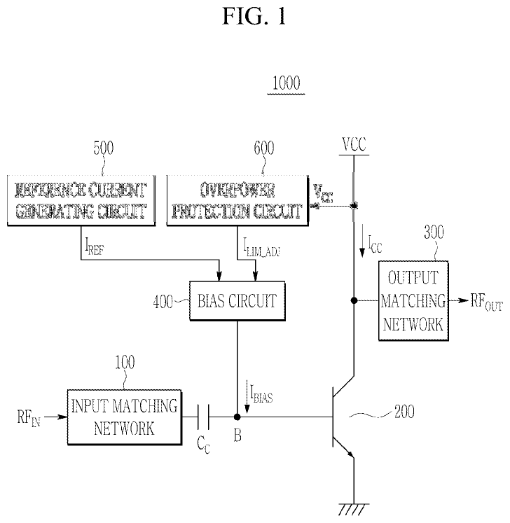

FIG. 1 illustrates a power amplifier 1000 according to an example.

As shown in FIG. 1, the power amplifier 1000 may include an input matching network 100, a power transistor 200, an output matching network 300, a bias circuit 400, a reference current generating circuit 500, and an overpower protection circuit 600.

The input matching network 100 may be connected to an input terminal (B) (for example, a base) of the power transistor 200, and it performs impedance matching between an input radio frequency (RF) signal RF_{IN} and the power transistor 200. The output matching network 300 may be connected to an output terminal (for example, a collector) of the power transistor 200, and it performs impedance matching between the output RF signal RF_{OUT} and a next stage (for example, a next stage of the power amplifier). The input matching network 100 and the output matching network 300 may each be implemented as a combination of at least one of a resistor, an inductor, and a capacitor.

The power transistor 200 may amplify power for the RF signal RF_{IN} inputted to the input terminal (B) and then output it to the output terminal (the collector). That is, an RF signal to be amplified may be inputted to the base of the power transistor 200, and the collector of the power transistor 200 may output the amplified RF signal. An emitter of the power transistor 200 may be connected to the ground, and although not shown in FIG. 1, a resistor may be additionally connected between the emitter of the power transistor 200 and the ground. The collector of the power transistor 200 may be connected to a power voltage V_{CC}, and the power transistor 200 may be operated by the power voltage V_{CC}. In FIG. 1, a current flowing through the output terminal (the collector) of the power transistor 200 is denoted as I_{CC}. Here, the current I_{CC} may be an output current of the power amplifier 1000. Also, the collector of the power transistor 200 can be connected to the power voltage V_{CC} through an inductor (not shown in FIG. 1) that performs an RF choke function.

On the other hand, in an abnormal state, a case in which the current I_{CC} excessively flows may occur. An example of the abnormal state may be a case in which a load impedance of the power transistor 200 considerably varies. If the current I_{CC} is excessively increased, the power transistor 200 may be damaged or destroyed. Hereinafter, such an abnormal state is referred to as an ‘overcurrent protection (OCP) state’.

In the abnormal state, the power voltage V_{CC} may become excessively high. An example of the abnormal state may be when the battery is unstable. Even when the power voltage VCC becomes excessively high, the power transistor 200 may be damaged or destroyed. Hereinafter, such an abnormal state is referred to as an ‘overvoltage protection (OVP) state’.

In order to prevent the OCP state and the OVP state, the overpower protection circuit 600 according to the example supplies an adjustment limiting current I_{LIM_ADJ} corresponding to the power voltage V_{CC} to the bias circuit 400 to protect the power transistor 200 from overpowering.

The power transistor 200 may be realized as various transistors such as a heterojunction bipolar transistor (HBT), a bipolar junction transistor (BJT), and an insulated gate bipolar transistor (IGBT). Although the power transistor 200 is shown as an n-type transistor in FIG. 1, it may be replaced with a p-type transistor.

A coupling capacitor Cc may be connected to the input terminal (the base) of the power transistor 200. The coupling capacitor Cc may perform a function of blocking a direct current (DC) component from an RF signal.

The bias circuit 400 receives a reference current I_{REF} from the reference current generating circuit 500 and the adjustment limiting current I_{LIM_ADJ} from the overpower protection circuit 600. The bias circuit 400 may generate a bias current I_{BIAS} required by the power transistor 200 by using the reference current I_{REF} and the adjustment limiting current I_{LIM_ADJ}. The bias current I_{BIAS} is supplied to the input terminal B of the power transistor 200, and a bias level (bias point) of the power transistor 200 may be set by the bias current I_{BIAS}. As an example, a maximum value of the bias current I_{BIAS} may be limited by the adjustment limiting current I_{LIM_ADJ}, which will be described in more detail below.

The reference current generating circuit 500 may generate the reference current I_{REF} and supply it to the bias circuit 400. As an example, the reference current generating circuit 500 may generate different reference currents I_{REF} according to a power mode of the power amplifier 1000. When the power mode is a high power mode, the reference current generating circuit 500 may generate a reference current I_{REF_HPM}. When the power mode is a low power mode, the reference current generating circuit 500 may generate a reference current I_{REF_LPM}. Here, an amount of the reference current I_{REF_HPM} may be larger than that of the reference current I_{REF_LPM}. A method for generating the reference current I_{REF} by the reference current generating circuit 500 may be conventional, so a detailed description thereof will be omitted.

The overpower protection circuit 600 may generate the adjustment limiting current I_{LIM_ADJ} and supply it to the bias circuit 400. The overpower protection circuit 600 may receive the power voltage V_{CC}, and may generate the adjustment limiting current I_{LIM_ADJ} in response to the power voltage V_{CC}. That is, the overpower protection circuit 600 may protect the power transistor 200 by generating the adjustment limiting current I_{LIM_ADJ} considering the OCP state as well as the OVP state. A typical overcurrent protection circuit may detect only the OCP state to generate a limiting current. In contrast, the overpower protection circuit 600 may generate a limiting current (that is, the adjustment limiting current) additionally reflecting the OVP state.

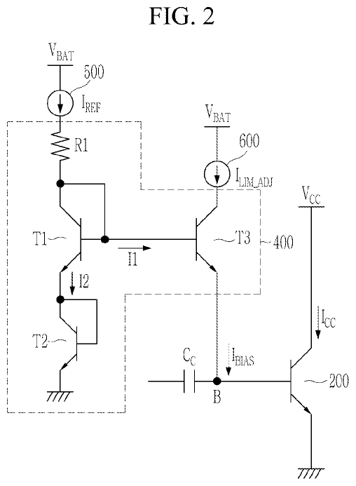

FIG. 2 illustrates an example of the bias circuit 400 according to the example.

As shown in FIG. 2, the bias circuit 400 may include a transistor T1, a transistor T2, a transistor T3, and a resistor R1.

The transistors T1 to T3 may be realized as various transistors such as a heterojunction bipolar transistor (HBT), a bipolar junction transistor (BJT), and an insulated gate bipolar transistor (IGBT). Although the transistors T1 to T3 are shown as n-type transistors in FIG. 2, they may be replaced with p-type transistors.

A base and a collector of the transistor T1 may be connected to each other, and the collector of the transistor T1 may be connected to a current source I_{REF} through the resistor R1. The transistor T1 may have a diode-connection structure. The transistor T1 serves to sink a current I2 from the current source I_{REF}. Since the reference current generating circuit 500 supplies the reference current I_{REF} to the bias circuit 400, the reference current generating circuit 500 is indicated as a current source I_{REF} in FIG. 2.

A base and a collector of the transistor T2 may be connected to each other, and the collector of the transistor T2 may be connected to an emitter of transistor T1. The transistor T2 may have a diode-connection structure, and an emitter of the transistor T2 may be connected to the ground. Although not shown in FIG. 2, a resistance may be added between the emitter of the transistor T2 and the ground.

A collector of the transistor T3 may be connected to a current source I_{LIM}, and a base of the transistor T3 may be connected to the base of the transistor T2. An emitter of the transistor T3 may be connected to the input terminal (B) of the power transistor 200, and may supply a bias current I_{BIAS} to the power transistor 200. Since the overpower protection circuit 600 supplies the adjustment limiting current I_{LIM_ADJ} to the bias circuit 400, the overpower protection circuit 600 is indicated as a current source I_{LIM_ADJ} in FIG. 2.

The reference current I_{REF} is divided into a current I1 and a current I2, and the current I1 may be inputted to the base of the transistor T3. Accordingly, the bias current I_{BIAS} may correspond to a sum of the adjustment limiting current I_{LIM_ADJ} and the current I1. Here, since the bias current I_{BIAS} corresponds to the base current of the power transistor 200, the bias current I_{BIAS} and the current I_{CC} may have a relationship of Equation 1 below.

$${I}_{BIAS} = \frac{{I}_{CC}}{β} \qquad ( Equation 1 )$$

In Equation 1, β is a common-emitter current gain of the power transistor 200.

As described above, in the OCP state, the current I_{CC} may increase. Referring to Equation 1, as the current I_{CC} increases, the bias current I_{BIAS} also increases. For this reason, an increase in the adjustment limiting current I_{LIM_ADJ} is required. In this case, the overpower protection circuit 600 may generate the adjustment limiting current I_{LIM} in response to the power voltage V_{CC}, and may provide the adjustment limiting current I_{LIM_ADJ} to the collector of the transistor T3. The overpower protection circuit 600 performing this operation will be described in detail below.

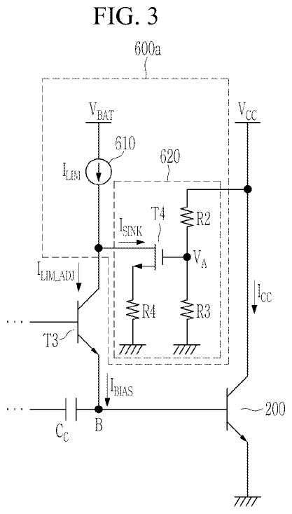

FIG. 3 illustrates an overpower protection circuit 600a according to an example.

As shown in FIG. 3, the overpower protection circuit 600a may include a limiting current source 610 and a sink current generating circuit 620.

The limiting current source 610 may generate a power voltage V_{BAT} by using a limit current I_{LIM}, and may provide a limiting current I_{LIM} to a collector of a transistor T3. Here, the limiting current I_{LIM} is a current provided in the OCP state, and a method of generating the limiting current I_{LIM} by the limiting current source 610 may be conventional, so a detailed description thereof will be omitted. As an example, the limiting current source 610 may include a plurality of transistors having a current mirror structure. The power voltage V_{BAT} may be a battery voltage.

The sink current generating circuit 620 may receive a power voltage V_{CC}, and may generate a sink current I_{SINK} in response to the power voltage V_{CC}. In addition, the sink current generating circuit 620 may sink as much as the sink current I_{SINK} from the limiting current I_{LIM} outputted from the limiting current source 610.

As shown in FIG. 3, the sink current generating circuit 620 may include a transistor T4, a resistor R2, a resistor R3, and a resistor R4. In FIG. 3, the transistor T4 may be a transistor such as an electric field effect transistor (FET), a bipolar transistor, or the like. In FIG. 3, the transistor T4 is shown as a n-type transistor, but may be a p-type transistor. In the following description, for better understanding and ease of description, it is assumed that the transistor T4 is an FET, but it may be replaced with another transistor. On the other hand, since a gate of the transistor serves as a control terminal, it may be referred to as a ‘control terminal’. Since a source of the transistor is one terminal of the transistor, it may be referred to as a ‘first terminal or second terminal’. In addition, since a drain of the transistor is one terminal of the transistor, it may be referred to as a ‘first terminal or second terminal’.

One end of the resistor R2 may be connected to the power voltage V_{CC}. That is, one end of the resistor R2 may be connected to a collector of a power transistor 200 to which the power voltage V_{CC} is applied. One end of the resistor R3 may be connected to the other end of the resistor R2, and the other end of the resistor R3 may be connected to the ground. In FIG. 3, a voltage at a junction between the resistor R2 and the resistor R3 is denoted as a ‘voltage V_{A}’. The voltage V_{A} may be inputted to a gate of the transistor T4.

The gate of the transistor T4 may be connected to the junction between resistor R2 and resistor R3. In addition, a drain of the transistor T4 may be connected to the collector of the transistor T3. That is, the drain of the transistor T4 may be connected to the limiting current source 610. The resistor R4 may be connected between the source of the transistor T4 and ground. The transistor T4 may sink as much as the sink current I_{SINK} from the limiting current I_{LIM} outputted from the limiting current source 610. That is, a current flowing through the drain of transistor T4 is the sink current I_{SINK}. In FIG. 3, the transistor T4 is shown to sink a current from the collector of the transistor T3 (that is, the limiting current I_{LIM}), but may sink a current from the base current of the transistor T3.

In FIG. 3, the power voltage V_{CC} is divided by the resistor R2 and the resistor R3. Accordingly, the voltage V_{A} has a relationship of Equation 2 below.

$${V}_{A} = \frac{R 3}{R 2 + R 3} \cdot {V}_{CC} \qquad ( Equation 2 )$$

The voltage V_{A} is inputted to the gate of the transistor T4. When the voltage V_{A} is higher than a threshold voltage of the transistor T4, the transistor T4 may be turned on. Here, the power voltage V_{CC} at which the transistor T4 is turned on is referred to as a ‘threshold power voltage V_{CC_TH}’. That is, when the power voltage is higher than the threshold power voltage V_{CC_TH}, the transistor T4 may be turned on.

When the transistor T4 is turned on, the transistor T4 may generate the sink current I_{SINK}. Since the sink current I_{SINK} flows to the source of the transistor T4 through the drain thereof, the sink current I_{SINK} may satisfy a relationship of Equation 3 below.

$${V}_{A} - {V}_{TH} = \frac{R 3}{R 2 + R 3} \cdot {V}_{CC} - {V}_{TH} = {I}_{SINK} \cdot R 4 \qquad ( Equation 3 )$$

In Equation 3, V_{TH} represents the threshold voltage of the transistor T4. A source voltage of the transistor T4 is ‘V_{A}-V_{TH}’, and Equation 2 may be applied instead of V_{A}. In addition, since the source voltage of the transistor T4 is I_{SINK}·R4, the relationship of Equation 3 may be derived.

Referring to Equation 3, the sink current I_{SINK} is proportional to the power voltage V_{CC}. As the power voltage VCC become higher, the sink current ISINK become larger. That is, as the power voltage V_{CC} increases, the sink current I_{SINK} increases.

When the power voltage V_{CC} is higher than the threshold power voltage V_{CC_TH}, the transistor T4 is turned on. In this case, the sink current I_{SINK} is generated, and the sink current I_{SINK} increases as the power voltage V_{CC} increases.

On the other hand, the adjustment limiting current I_{LIM_ADJ} may have a relationship of Equation 4 below.

$${I}_{LIM\_ADJ} = {I}_{LIM} - {I}_{SINK} \qquad ( Equation 4 )$$

Referring to Equation 4, the adjustment limiting current I_{LIM_ADJ} decreases as the sink current I_{SINK} increases. That is, when the power voltage V_{CC} becomes higher, the adjustment limiting current I_{LIM_ADJ} may become smaller.

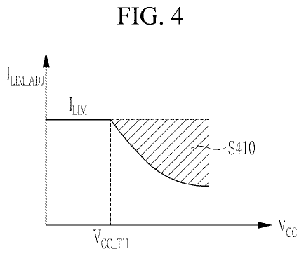

FIG. 4 illustrates a graph of a relationship between the power voltage V_{CC} and the adjustment limiting current I_{LIM_ADJ} in the overpower protection circuit 600a of FIG. 3.

When the power voltage V_{CC} is lower than the threshold power voltage V_{CC_TH}, the transistor T4 is turned off. In this case, the sink current generating circuit 620 does not generate the sink current I_{SINK}. Accordingly, the adjustment limiting current I_{LIM_ADJ} has the same value as the limit current I_{LIM}.

When the power voltage V_{CC} is higher than the threshold power voltage V_{CC_TH}, the transistor T4 is turned on. Referring to Equation 3, the sink current I_{SINK} increases as the power voltage V_{CC} increases. Referring to Equation 4, when the power voltage V_{CC} increases, the adjustment limiting current I_{LIM_ADJ} decreases. As shown in FIG. 4, when the power voltage V_{CC} is greater than or equal to the threshold power voltage V_{CC_TH}, the adjustment limiting current I_{LIM_ADJ} gradually decreases.

In FIG. 4, an area S410 is not included in the overpower protection circuit 600a according to the example. Generally, an OCP operation and an OVP operation are independently performed, and in this case, the area S410 may exist. In the area S410, both a voltage and a current are excessively increased, which may be a problem in terms of power. In contrast, since the overpower protection circuit 600a according to the example does not have the area S410, it may safely protect the power transistor 200 from a power point of view. That is, in a situation in which an excessive current I_{CC} flows due to a low load impedance, or in a situation in which an excessive power voltage V_{CC} is applied during charging or turning on/off of the battery, the overpower protection circuit 600a according to the example safely protects the power transistor 200.

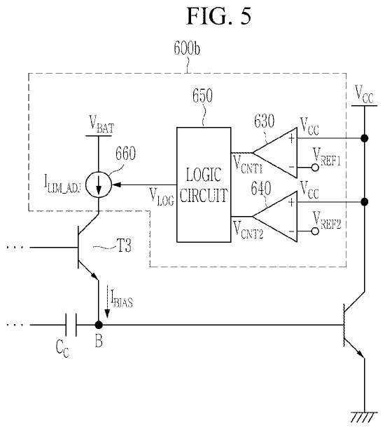

FIG. 5 illustrates an overpower protection circuit 600b according to another embodiment.

As shown in FIG. 5, the overpower protection circuit 600b according to another example may include a first comparator 630, a second comparator 640, a logic circuit 650, and an adjustment limiting current source 660.

The first comparator 630 may include a non-inverting terminal (+) and an inverting terminal (−). A power voltage V_{CC} may be inputted to the non-inverting terminal (+) of the first comparator 630, and a reference voltage V_{REF1} may be inputted to the inverting terminal (−) of the first comparator 630. The non-inverting terminal (+) of the first comparator 630 may be connected to the power voltage V_{CC}. That is, the non-inverting terminal (+) of the first comparator 630 may be connected to a collector of a power transistor 200 to which the power voltage V_{CC} is applied. Here, the reference voltage V_{REF1} is a voltage arbitrarily set to detect an overvoltage state of the power voltage V_{CC}. The first comparator 630 may compare the power voltage V_{CC} and the reference voltage V_{REF1} to output a control voltage V_{CNT1}. When the power voltage V_{CC} is higher than the reference voltage V_{REF1}, the first comparator 630 may output a high level control voltage V_{CNT1_H}. When the power voltage V_{CC} is lower than the reference voltage V_{REF1}, the first comparator 630 may output a low level control voltage V_{CNT1_L}.

The second comparator 640 may include a non-inverting terminal (+) and an inverting terminal (−). The power voltage V_{CC} may be inputted to the non-inverting terminal (+) of the second comparator 640, and a reference voltage V_{REF2} may be inputted to the inverting terminal (−) of the second comparator 640. The non-inverting terminal (+) of the second comparator 640 may be connected to the power voltage V_{CC}. That is, the non-inverting terminal (+) of the second comparator 640 may be connected to the collector of a power transistor 200 to which the power voltage V_{CC} is applied. Here, the reference voltage V_{REF2} is a voltage arbitrarily set to detect an overvoltage state of the power voltage V_{CC}. The reference voltage V_{REF2} may have a higher level than the reference voltage V_{REF1}. The second comparator 640 may compare the power voltage V_{CC} and the reference voltage V_{REF2} to output a control voltage V_{CNT2}. When the power voltage V_{CC} is higher than the reference voltage V_{REF2}, the second comparator 640 may output a high level control voltage V_{CNT2_H}. When the power voltage V_{CC} is lower than the reference voltage V_{REF2}, the second comparator 640 may output a low level control voltage V_{CNT2_L}.

The logic circuit 650 may receive the control voltage V_{CNT1} of the first comparator 630 and the control voltage V_{CNT2} of the second comparator 640 to generate a logic signal V_{LOG}. The logic circuit 650 may output the generated logic signal V_{LOG} to the adjustable limiting current source 660. Here, the logic signal V_{LOG} may include a logic signal V_{LOG1}, a logic signal V_{LOG2}, and a logic signal V_{LOG3}. When the low level control voltage V_{CNT1_L} is inputted from the first comparator 630 and the low level control voltage V_{CNT2_L} is inputted from the second comparator 640, the logic circuit 650 may generate a logic signal V_{LOG1}. When the high level control voltage V_{CNT1_H} is inputted from the first comparator 630 and the low level control voltage V_{CNT2_L} is inputted from the second comparator 640, the logic circuit 650 may generate a logic signal V_{LOG2}. When the high level control voltage V_{CNT1_H} is inputted from the first comparator 630 and the high level control voltage V_{CNT2_H} is inputted from the second comparator 640, the logic circuit 650 may generate a logic signal V_{LOG3}. A method of the logic circuit 650 generating a logic signal according to an input signal may be conventional, so a detailed description thereof will be omitted.

The adjustment limiting current source 660 may be connected between the power voltage V_{BAT} and the collector of the transistor T3. The adjustment limiting current source 660 may generate the adjustment limit current I_{LIM_ADJ} by using the power voltage V_{BAT} and the logic signal V_{LOG}, and may provide the adjustment limiting current I_{LIM_ADJ} to the collector of the transistor T3.

When the logic signal V_{LOG} is the logic signal V_{LOG1}, the adjustment limiting current source 660 may generate and output the limiting current I_{LIM}. When the logic signal V_{LOG} is the logic signal V_{LOG2}, the adjustment limiting current source 660 may generate and output the adjustment limiting current I_{LIM_ADJ1}. When the logic signal V_{LOG} is the logic signal V_{LOG3}, the adjustment limiting current source 660 may generate and output the adjustment limiting current I_{LIM_ADJ2}. Here, the adjustment limiting current I_{LIM_ADJ1} may have a value smaller than the adjustment limiting current I_{LIM}, and the adjustment limiting current I_{LIM_ADJ2} may have a smaller value than the adjustment limiting current I_{LIM_ADJ1}. A method of the adjustment limiting current source 660 generating the limiting current I_{LIM} and the adjustment limiting current I_{LIM_ADJ} by using the logic signal V_{LOG} may be conventional, so a detailed description thereof will be omitted. As an example, the adjustment limiting current source 660 may include a plurality of transistors having a current mirror structure, and the turning on and off of the plurality of transistors may be controlled by the logic signal V_{LOG}.

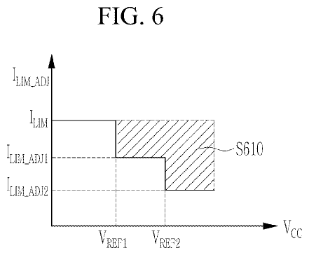

FIG. 6 illustrates a graph of a relationship between the power voltage V_{CC} and the adjustment limiting current I_{LIM_ADJ} in the overpower protection circuit 600b of FIG. 5.

When the power voltage V_{CC} is lower than the reference voltage V_{REF1}, the first comparator 630 may output the low level control voltage V_{CNT1_L}, and the second comparator 640 may also output the low level control voltage V_{CNT2_L}. In this case, the logic circuit 650 may generate the logic signal V_{LOG1} in response to the low level control voltage V_{CNT1_L} and the low level control voltage V_{CNT2_L}. The adjustment limiting current source 660 may generate and output the limiting current I_{LIM} in response to the logic signal V_{LOG1}.

When the power voltage V_{CC} is higher than the reference voltage V_{REF1} and lower than the reference voltage V_{REF2}, the first comparator 630 may output the high level control voltage V_{CNT1_H}, and the second comparator 640 may output the low level control voltage V_{CNT2_L}. In this case, the logic circuit 650 may generate the logic signal V_{LOG2} in response to the high level control voltage V_{CNT1_H} and the low level control voltage V_{CNT2_L}. The adjustment limiting current source 660 may generate and output the adjustment limiting current I_{LIM_ADJ1} in response to the logic signal V_{LOG2}. That is, when the power voltage V_{CC} is higher than the reference voltage V_{REF1} and lower than the reference voltage V_{REF2}, the adjustment limiting current source 660 may generate the smaller adjustment limiting current I_{LIM_ADJ1} than the limiting current I_{LIM} to provide it to the collector of the transistor T3.

When the power voltage V_{CC} is higher than the reference voltage V_{REF2}, the first comparator 630 may output the high level control voltage V_{CNT1_H}, and the second comparator 640 may output the high level control voltage V_{CNT2_H}. In this case, the logic circuit 650 may generate the logic signal V_{LOG3} in response to the high level control voltage V_{CNT1_H} and the high level control voltage V_{CNT2_H}. The adjustment limiting current source 660 may generate and output the adjustment limiting current I_{LIM_ADJ2} in response to the logic signal V_{LOG3}. When the power voltage V_{CC} is higher than the reference voltage V_{REF2}, the adjustment limiting current source 660 may generate the adjustment limiting current I_{LIM_ADJ2} smaller than the adjustment limiting current I_{LIM_ADJ1} to provide it to the collector of the transistor T3.

In FIG. 6, an area S610 is not included in the overpower protection circuit 600b. Generally, an OCP operation and an OVP operation are independently performed, and in this case, the area S610 may exist. In the area S610, both a voltage and a current are excessively increased, which may be a problem in terms of power. In contrast, since the overpower protection circuit 600b does not have the area S610, it may safely protect the power transistor 200 from a power point of view. That is, in a situation in which the excessive current I_{CC} flows due to a low load impedance, or in a situation in which the excessive power voltage V_{CC} is applied during charging or turning the battery on/off, the overpower protection circuit 600b may safely protect the power transistor 200.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed to have a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A power amplifier comprising:
a power transistor configured to receive a power voltage;
a first transistor including a first terminal configured to provide a bias current to the power transistor; and
an overpower protection circuit configured to generate a first current corresponding to the power voltage and to provide the first current to a second terminal of the first transistor,
wherein the overpower protection circuit includes:
a limiting current source configured to provide a limiting current to the second terminal of the first transistor; and
a sink current generating circuit including a second transistor that includes a control terminal to which a voltage corresponding to the power voltage is applied and a first terminal connected to the second terminal of the first transistor, and configured to sink a second current from the limiting current.

2. The power amplifier of claim 1, wherein
when the power voltage increases, the second current increases, and the first current decreases.

3. The power amplifier of claim 1, wherein
when the power voltage is higher than a first voltage, the first current decreases as the power voltage increases.

4. The power amplifier of claim 1, wherein
the first current has a value obtained by subtracting the second current from the limiting current.

5. The power amplifier of claim 1, wherein
the sink current generating circuit further includes a first resistor including a first end connected to the power voltage and a second resistor connected between a second end of the first resistor and a ground, and
the second end of the first resistor is connected to the control terminal of the second transistor.

6. The power amplifier of claim 5, wherein
the sink current generating circuit further includes a third resistor connected to a second terminal of the second transistor and the ground.

7. The power amplifier of claim 1, wherein
the second current flows from the second terminal of the first transistor to the first terminal of the second transistor.

8. The power amplifier of claim 1, wherein
the first terminal of the first transistor is an emitter, and the second terminal of the first transistor is a collector.

9. A power amplifier comprising:
a power transistor configured to receive a power voltage;
a first transistor including a first terminal configured to provide a bias current to the power transistor; and
an overpower protection circuit configured to generate a first current corresponding to the power voltage and to provide the first current to a second terminal of the first transistor,
wherein the overpower protection circuit is configured to generate the first current having a first value when the power voltage is higher than a first reference voltage, and the overpower protection circuit is configured to generate the first current having a second value when the power voltage is higher than a second reference voltage, and
the second reference voltage is higher than the first reference voltage, and the second value is smaller than the first value.

10. The power amplifier of claim 9, wherein
the overpower protection circuit is configured to generate the first current having a third value when the power voltage is lower than the first reference voltage, and
the third value is larger than the first value.

11. The power amplifier of claim 9, wherein
the overpower protection circuit includes:
a first comparator configured to compare the power voltage to the first reference voltage; and
a second comparator configured to compare the power voltage to the second reference voltage.

12. The power amplifier of claim 11, wherein
the overpower protection circuit includes:
a logic circuit configured to receive an output of the first comparator and an output of the second comparator and to generate a logic signal, and
a current source configured to generate the first current in response to the logic signal.

13. The power amplifier of claim 9, wherein
the first terminal of the first transistor is an emitter, and the second terminal of the first transistor is a collector.

14. A power amplifier comprising:
a power transistor configured to receive a power voltage;
a transistor configured to provide a bias current to the power transistor; and
an overpower protection circuit configured to:
generate a first current having a first value based on a comparison between the power voltage and a first reference voltage;
generate a second current having a second value based on a comparison between the power voltage and a second reference voltage; and
provide the first current or the second current to the transistor.

15. The power amplifier of claim 14, wherein the second reference voltage is higher than the first reference voltage, and the second value is smaller than the first value.

16. The power amplifier of claim 14, wherein the overpower protection circuit includes:
a limiting current source configured to provide a limiting current to the transistor; and
a sink current generating circuit including a second transistor that includes a control terminal to which a voltage corresponding to the power voltage is applied and a first terminal connected to the transistor, and configured to sink a second current from the limiting current.
